(19) United States
(12) Patent Application Publication
(10) Pub. No.: US 2024/0081057 A1
(43) Pub. Date: Mar. 7, 2024

(54) ELECTRONIC DEVICES INCLUDING A METAL SILICIDE MATERIAL OVER A SOURCE CONTACT, AND RELATED MEMORY DEVICES, SYSTEMS, AND METHODS OF FORMING

(71) Applicant: Micron Technology, Inc., Boise, ID (US)

(72) Inventors: Jordan D. Greenlee, Boise, ID (US); John D. Hopkins, Meridian, ID (US); Andrew L. Li, Boise, ID (US)

(21) Appl. No.: 17/929,933

(22) Filed: Sep. 6, 2022

(51) Int. Cl. H01L 27/11582; H01L 21/285; H01L 27/11565

(52) U.S. Cl. CPC H01L 27/11582; H01L 21/28518; H01L 27/11565

(57) ABSTRACT

An electronic device includes a source contact adjacent to a source stack, the source stack including one or more conductive materials, tiers of alternating conductive material and dielectric materials adjacent to the source contact, pillars extending vertically through the tiers and the source contact and at least partially into the source contact, a fill material extending vertically through the tiers to the source contact, and a metal silicide material between the fill material and an upper surface of the source contact. Related devices, systems, and methods are also disclosed.

### TECHNICAL FIELD

The disclosure, in various embodiments, relates generally to the field of electronic devices and electronic device fabrication. More particularly, the disclosure relates to electronic devices including a metal silicide material over a source contact, and to related methods and systems.

### BACKGROUND

A continuing goal of the electronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes transistor/memory cell pillars extending through a stack structure of tiers of alternating dielectric materials and conductive materials. The conductive materials of the tiers function as control gates. Such a configuration permits a greater number of transistors/memory cells to be located in a unit of die area by building the array upwards (e.g., vertically) on a die, as compared to structures with conventional planar (e.g., two-dimensional) arrangements of transistors/memory cells.

In conventional 3D NAND Flash memory devices, contact between channel materials of the transistor/memory cell pillars is achieved by a laterally-oriented source contact, which may be a doped polysilicon material. The conductive materials of the transistors/memory cells are formed by a so-called “replacement gate” process using openings extending through the stack structure. In the replacement gate process, sacrificial materials are removed via a conventional wet etch process prior to forming the conductive materials. However, the etch chemistries and conditions used in the replacement gate process may also etch into the laterally-oriented source contact, decreasing reliability, durability, and performance of the vertical memory array.

### BRIEF DESCRIPTION OF THE DRAWINGS

FIGS. 1A through 1D are cross-sectional views at various stages of forming an electronic structure according to embodiments of the disclosure;

FIG. 1E is a top-down cross-sectional view of the electronic structure of FIG. 1D taken along the A-A line;

FIG. 1F is a cross-sectional view of the electronic structure of FIGS. 1A through 1E after annealing;

FIG. 1G is a top-down cross-sectional view of the electronic structure of FIG. 1F taken along the B-B line;

FIG. 1H is a cross-sectional view of the electronic structure of FIGS. 1A through 1F after the replacement gate process;

FIG. 1I is a top-down cross-sectional view of the electronic structure of FIG. 1H taken along the C-C line;

FIG. 2 is a partial cutaway perspective view of an electronic device according to embodiments of the disclosure;

FIG. 3 is a schematic block diagram of an electronic system according to embodiments of the disclosure; and

FIG. 4 is a schematic block diagram of a process-based system according to embodiments of the disclosure.

### DETAILED DESCRIPTION

Electronic devices (e.g., apparatuses, semiconductor device, memory devices) including a metal silicide material over a source contact and related systems and methods of forming the electronic devices are described herein. The electronic devices include a source contact overlying a source stack and a stack structure including tiers of alternating conductive materials and dielectric materials overlying the semiconductor source. Memory pillars extend vertically through the stack structure and the source contact and at least partially into the source stack. The memory pillars include a channel material. The source contact is laterally adjacent to the channel material of the memory pillars and is operably coupled to the memory pillars and the source stack. An opening extends vertically through the stack structure to the source contact. A metal silicide material is on an upper surface of the source contact defining the opening. A metal material may be disposed on the metal silicide material.

The metal silicide material may advantageously protect the source contact during subsequent processing acts conducted during formation of the electronic device. For example, the metal silicide material may exhibit a low etch rate when exposed to the etch chemistries and conditions used in the replacement gate process. The metal silicide material protects the source contact from etch chemistries and conditions used in the replacement gate process, substantially decreasing and/or eliminating damage to and degradation of the source contact during the replacement gate process. As a result, the source contact may exhibit improved performance, durability, and reliability as compared to conventional source contacts formed by conventional methods and that lack the metal silicide material.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed using conventional techniques.

Unless otherwise indicated, the materials described herein may be formed by conventional techniques including, but not limited to, spin coating, blanket coating, chemical vapor deposition (CVD), atomic layer deposition (ALD), plasma enhanced ALD, physical vapor deposition (PVD) (including sputtering, evaporation, ionized PVD, and/or plasma enhanced CVD), or epitaxial growth. Alternatively, the materials may be grown in situ. Depending on the specific material to be formed, the technique for depositing or growing the material may be selected by a person of ordinary skill in the art. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, electronic device, or electronic system. Variations from the shaped depicted in the drawings as a result, for example, of manufacturing techniques and/or tolerances are to be expected. Thus, embodiments described herein are not to be construed as being limited to the particular shapes or regions as illustrated, but include deviations in shapes that results, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the term “configured” refers to a size, shape, material composition, and arrangement of one or more of at least one structure and at least one apparatus facilitating operation of one or more of the structure and the apparatus in a pre-determined way.

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, the term “selectively etchable” means and includes a material that exhibits a greater etch rate responsive to exposure to a given etch chemistry and/or process conditions relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the term “sacrificial,” when used in reference to a material or a structure, means and includes a material, structure, or a portion of a material or structure that is formed during a fabrication process but which is removed (e.g., substantially removed) prior to completion of the fabrication process.

As used herein, the term “stack” or “stacks” means and includes a feature having one or more materials vertically adjacent to one another, the stacks may include alternating dielectric materials and conductive materials, such as alternating oxide materials and metal materials or alternative oxide materials and polysilicon materials. Depending on the stage of fabrication of the electronic device containing the stacks, the stacks may alternatively include alternating dielectric materials and nitride materials, such as alternating oxide materials and silicon nitride materials.

As used herein, the term “opening” means and include a volume extending through at least one structure or at least one material, leaving a void (e.g., gap) in that at least one structure or at least one material, or a volume extending between structures or materials, leaving a gap between the structures or materials. Unless otherwise described, an “opening” is not necessarily empty of material. That is, an “opening” is not necessarily void space. An “opening” formed in or between structures or materials may comprise structure(s) or material(s) other than that in or between which the opening is formed. And, structure(s) or material(s) “exposed” within an “opening” is (are) not necessarily in contact with an atmosphere or non-solid environment. Structure(s) or material(s) “exposed” within an “opening” may be adjacent or in contact with other structure(s) or material(s) that is (are) disposed within the “opening.”

As used herein, “conductive material” means and includes an electrically conductive material, such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pa), platinum (Pt), copper (Cu), silver (Ag), gold (Au), aluminum (Al)), an alloy (e.g., a Co-based alloy, an Fe-based alloy, a Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and conductively-doped semiconductor material (e.g., conductively-doped polysilicon, conductively-doped germanium (Ge), conductively-doped silicon germanium (SiGe)).

As used herein, “dielectric material” means and includes an electrically insulative material, such as one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), and a magnesium oxide (MgOₓ)), at least one dielectric nitride material (e.g., a silicon nitride (SiN_{y})), at least one dielectric oxynitride material (e.g., silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein represent a material that contains an average ratio of “x” atoms of one element, “y” atoms of another element, and “z” atoms of an additional element (if any) for every atom of another element. Values of “x,” “y,” and “z” (if any) may be positive real integers or positive real non-integers.

As used herein, the term “substantially” in reference to a given parameter, property, or condition means and includes to a degree that one of ordinary skill in the art would understand that the given parameter, property, or condition is met with a degree of variance, such as acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, the term “substrate” means and includes a material (e.g., a base material) or construction upon which additional materials are formed. The substrate may be an electronic substrate, a semiconductor substrate, a base semiconductor layer on a supporting structure, an electrode, an electronic substrate having one or more materials, layers, structures, or regions formed thereon. The materials on the electronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOT”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

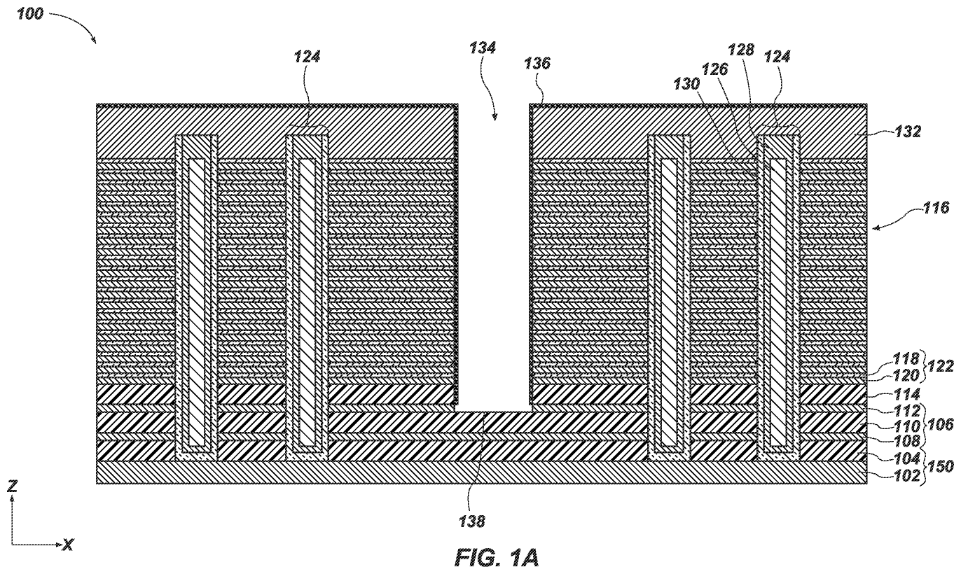

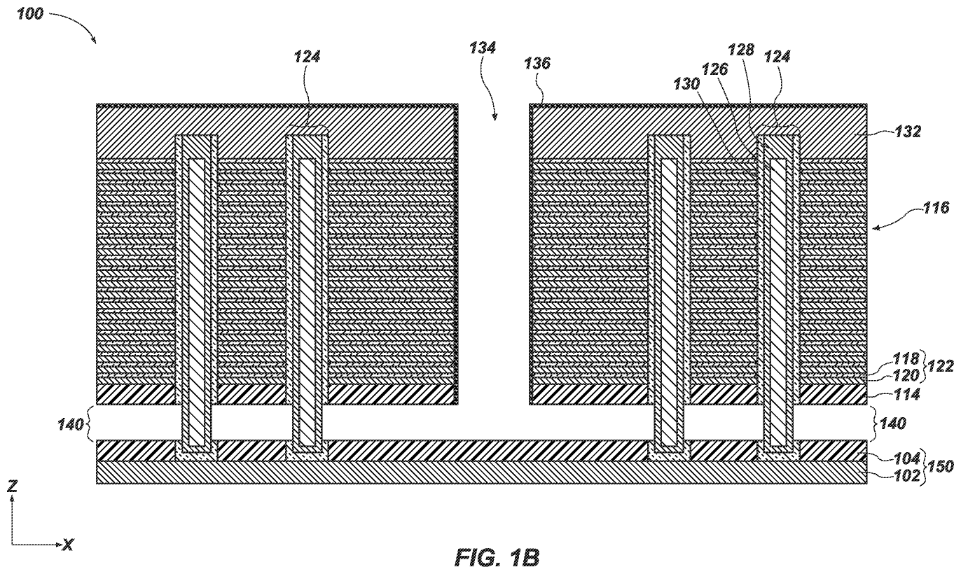

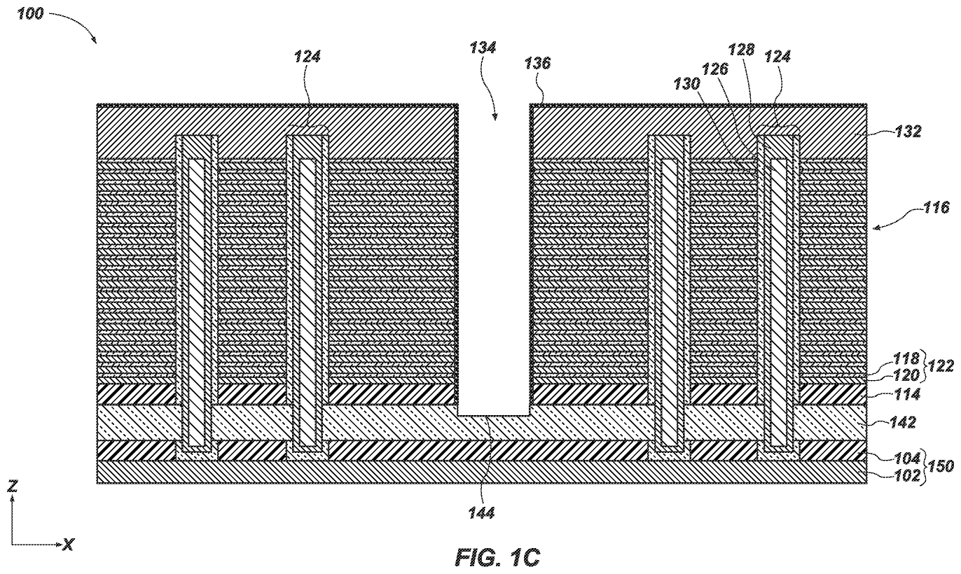

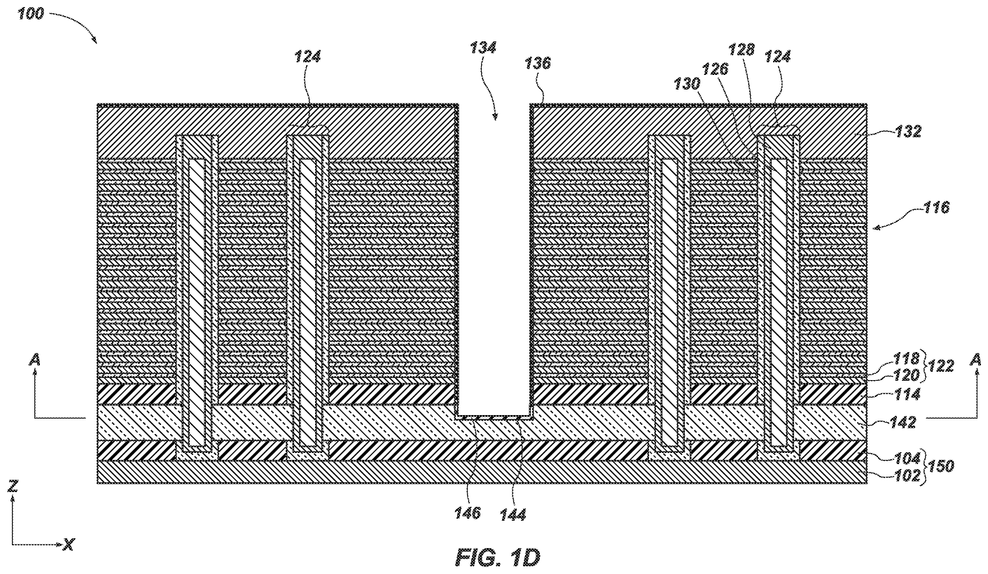

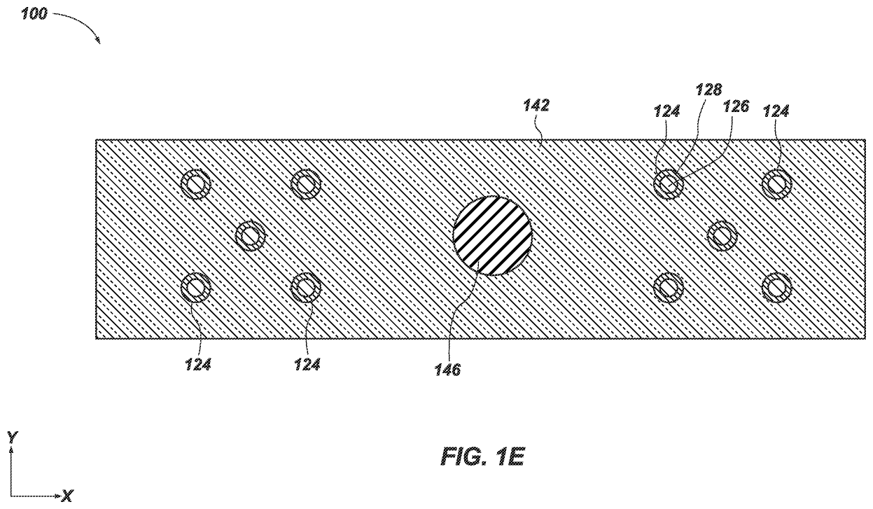

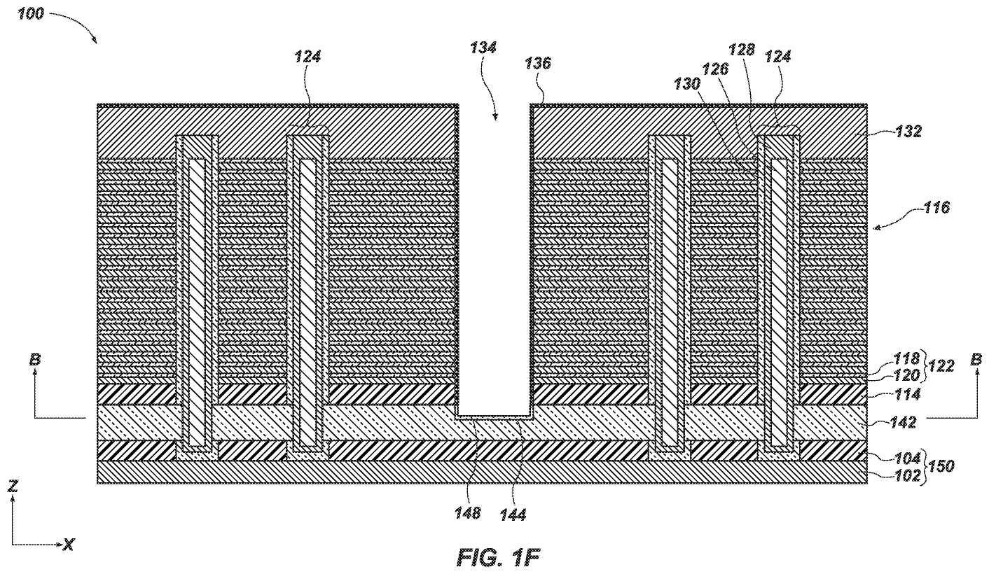

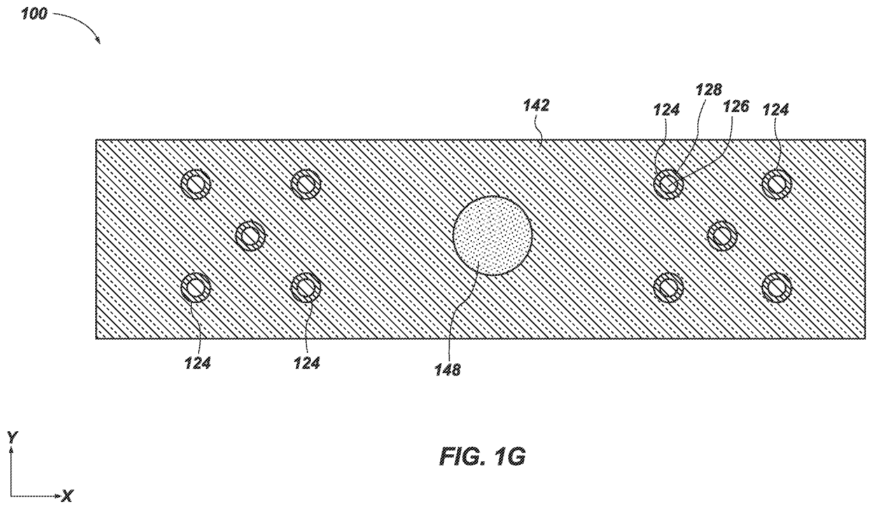

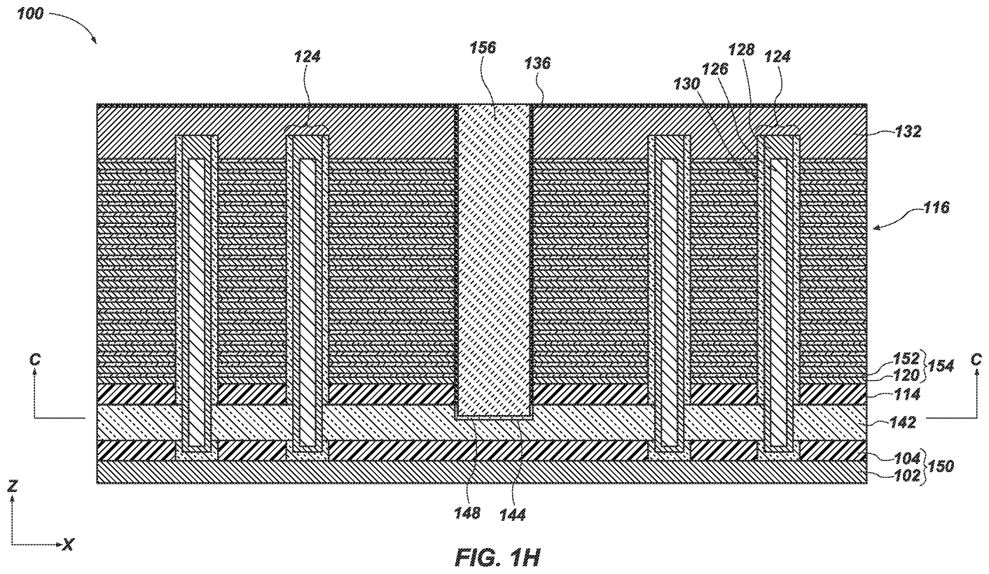

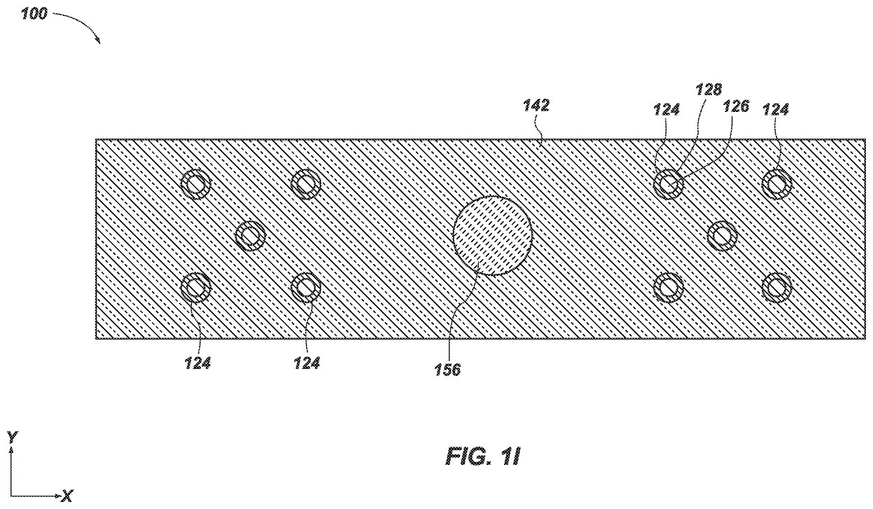

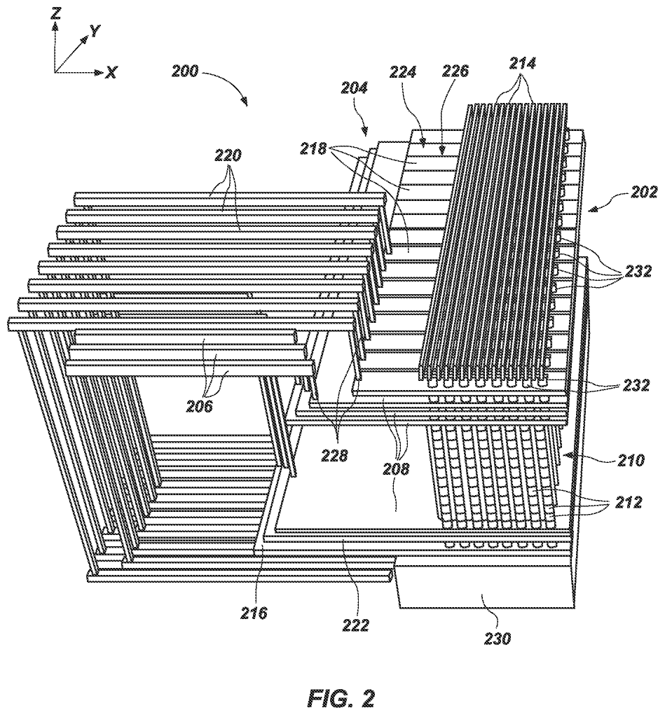

FIGS. 1A through 1I illustrate an electronic structure 100 (e.g., a semiconductor structure) at different processing stages of a method of forming an electronic device (e.g., a memory device, such as a 3D NAND Flash memory device), according to embodiments of this disclosure. For simplicity, the formation of a single opening through which a material of a source contact is formed is illustrated, but it will be understood by one of ordinary skill in the art that the method may include simultaneously forming multiple (e.g., more than one of, an array of) openings in which the material of the source contact is ultimately to be formed. For convenience in describing FIGS. 1A through 1I, a first direction is defined, shown in FIGS. 1A through 1I, as the X-direction. A second direction, which is transverse (e.g., perpendicular) to the first direction is defined, shown in FIGS. 1A through 1D, 1F, and 1H as the Z-direction. A third direction, which is transverse to the first and second directions is defined, as shown in FIGS. 1E, 1G, and 1I as the Y-direction. Similar directions are defined, as shown in FIG. 2, as discussed in greater detail below.

The electronic structure 100 according to embodiments of the disclosure may be formed as shown in FIGS. 1A through 1I, which are cross-sectional views of the electronic structure 100 during fabrication. Referring to FIG. 1A, a semiconductor material 104 may be formed overlying a base material 102. The base material 102 may, for example, include a conductive material, such as a source, vertically adjacent to a substrate. The semiconductor material 104 may be formed of and include a polysilicon material (e.g., a doped polysilicon material). The semiconductor material 104 and the base material 102 collectively form a source stack 150.

A source contact sacrificial structure 106 may be formed over the source stack 150. The source contact sacrificial structure 106 may include a first sacrificial material 108, a second sacrificial material 110, and a third sacrificial material 112. The first sacrificial material 108, the second sacrificial material 110, and the third sacrificial material 112 may be formed by conventional techniques. Materials of the first sacrificial material 108, the second sacrificial material 110, and the third sacrificial material 112 may be selectively removable (e.g., selectively etchable) relative to one another and relative to other materials of the electronic structure 100. The first sacrificial material 108 and the third sacrificial material 112 may be dielectric materials, such as a silicon oxide material or a silicon nitride material, that are selectively removable relative to other materials of the electronic structure 100. In some embodiments, the first sacrificial material 108 and the third sacrificial material 112 are the same material (e.g., exhibit the same chemical composition). In some embodiments, the second sacrificial material 110 is a polysilicon material (e.g., a doped polysilicon material). However, other combinations of dielectric materials and semiconductor materials that are selectively removable relative to one another may be used in the source contact sacrificial structure 106. The source contact sacrificial structure 106 is depicted in FIGS. 1A-1G as being formed of and including three materials. However, the source contact sacrificial structure 106 may be formed of and include one material, two materials, or more than three materials. As discussed in greater detail below, removal of one or more materials of the source contact sacrificial structure 106 forms an opening that provides lateral access for a subsequently formed source contact to contact pillars (e.g., memory cell pillars).

A semiconductor material 114 may be formed over the source contact sacrificial structure 106. The semiconductor material 114 may be formed of and include a polysilicon material (e.g., a doped polysilicon material). The semiconductor material 114 may be the same material (e.g., exhibit the same chemical composition) as the semiconductor material 104.

A stack structure 116 may be formed to include vertically alternating (e.g., in the Z-direction) nitride materials 118 and dielectric materials 120 overlying the semiconductor material 114. The nitride materials 118 and the dielectric materials 120 may each individually be formed through one or more conventional processes (e.g., a PVD process, a CVD process, an ALD process) to form the stack structure 116. The nitride materials 118 may subsequently be replaced with conductive materials via the replacement gate process. A vertically adjacent nitride material 118 and dielectric material 120 form a tier 122, or a subsequently formed vertically adjacent conductive material 152 (see FIG. 1H) and dielectric material 120, form a tier 154. FIGS. 1A through 1I depict the stack structure 116 including one deck. However, the stack structure 116 may include multiple (e.g., two or more) decks. An inter-deck region (not shown) may be disposed between the decks.

Pillars 124 (e.g., memory pillars) are formed which vertically extend through the tiers 122, the semiconductor material 114, the source contact sacrificial structure 106, and at least partially into the semiconductor material 104. The pillars 124 may include a fill material 126 surrounded by a channel material 128 and cell films 130. The channel material 128 is not limited to the channel configuration illustrated in FIG. 1A, and may exhibit a different configuration than that illustrated. The cell films 130 may include, for example, one or more of a tunnel dielectric material, a charge trap material, and a charge blocking material. Sidewalls of the pillars 124 may be substantially vertical or sloped. The pillars 124 may be formed using conventional processes, which are not described in detail herein. As a non-limiting example, the cell films 130 and the channel material 128 may each be substantially conformally formed by conventional techniques, such as by a conventional CVD process or a conventional ALD process. A dielectric material 132 may be formed by conventional techniques over the pillars 124 and the stack structure 116, as shown in FIG. 1A.

An opening 134 (e.g., a slit, a slot) is formed and vertically extends through the dielectric material 132, the tiers 122 of the stack structure 116, the semiconductor material 114, and the third sacrificial material 112 of the source contact sacrificial structure 106. The opening 134 may be formed by removing a portion of the tiers 122, the semiconductor material 114, and the third sacrificial material 112. The opening 134 may have any suitable configuration. The opening 134 is defined by sidewalls of the tiers 122, the semiconductor material 114, and the third sacrificial material 112, and an upper surface 138 of the second sacrificial material 110. The sidewalls of the tiers 122, the semiconductor material 114, and the third sacrificial material 112 may be substantially vertical or may be sloped. The opening 134 may be a high aspect ratio (HAR) opening, such as having an HAR of at least about 10:1, at least about 20:1, at least about 50:1, at least about 100:1, at least about 150:1, or at least about 200:1.

A liner 136 may be substantially conformally formed by conventional techniques over the electronic structure 100. The liner 136 may substantially continuously extend along an upper surface of the dielectric material 132, along sidewalls of the tiers 122 and the third sacrificial material 112, and along an upper surface of the second sacrificial material 110. The liner 136 may be formed of and include a dielectric material, a semiconductive material, or a conductive material. A portion of the liner 136 may be removed from an upper surface 138 of the second sacrificial material 110 and sidewalls of the third sacrificial material 112 within the opening 134, exposing the second sacrificial material 110. The portion of the liner 136 may be removed by conventional techniques, such as, for example, a punch etch process.

Referring to FIG. 1B, the source contact sacrificial structure 106 (FIG. 1A) and portions of the cell films 130 laterally adjacent to the source contact sacrificial structure 106 are removed to form a source contact opening 140. The source contact sacrificial structure 106 and the portions of the cell films 130 may be removed by conventional techniques, such as by one or more wet etch processes. Conventional etch chemistries and conditions may be used to remove the source contact sacrificial structure 106 and the portions of the cell films 130 depending on the material(s) used for the first sacrificial material 108, the second sacrificial material 110, the third sacrificial material 112, and the cell films 130. The etch chemistries and etch conditions may selectively remove the source contact sacrificial structure 106 and the portions of the cell films 130 without substantially removing the semiconductor material 104, the semiconductor material 114, or the channel material 128.

The second sacrificial material 110 may be removed before removing the first sacrificial material 108, the third sacrificial material 112, and the portions of the cell films 130. For example, the second sacrificial material 110 may be selectively removed (e.g., selectively etched) without substantially removing the first sacrificial material 108, the third sacrificial material 112, or the portions of the cell films 130. The second sacrificial material 110 may be removed by conventional techniques, such as by a wet etch process. Conventional etch chemistries and conditions may be used to selectively remove the second sacrificial material 110 relative to the first sacrificial material 108, the third sacrificial material 112, and the cell films 130 depending on the material(s) used for the second sacrificial material 110.

The first sacrificial material 108, the third sacrificial material 112, and the portions of the cell films 130 may be selectively removed via one or more etching processes without substantially removing the liner 136, the semiconductor material 104, and the semiconductor material 114. The first sacrificial material 108, the third sacrificial material 112, and the cell films 130 may be formed of and include similar materials (e.g., similar chemical composition) and therefore may exhibit similar etch rates. The first sacrificial material 108, the third sacrificial material 112, and the portions of the cell films 130 may be removed at substantially the same time. The semiconductor material 114 is protected from (e.g., not exposed to) the etch chemistries and etch conditions by the liner 136 and the third sacrificial material 112.

Removing the source contact sacrificial structure 106 and the portions of the cell films 130 forms the source contact opening 140 and exposes a bottom surface of the semiconductor material 114, an upper surface of the semiconductor material 104, and portions of the channel material 128 laterally adjacent to the source contact opening 140. The source contact opening 140 may laterally extend between adjacent channel materials 128 of the pillars 124 and vertically extend between the upper surface of the semiconductor material 104 and the bottom surface of the semiconductor material 114, as shown in FIG. 1B. A thickness (e.g., height) of the source contact opening 140 corresponds to a thickness of the source contact sacrificial structure 106.

Referring to FIG. 1C, a source contact material 142 (e.g., a source contact) is substantially conformally formed over the electronic structure 100, within the opening 134, and within the source contact opening 140 by conventional techniques, such as by a conventional CVD process or by a conventional ALD process, using conventional processing equipment. The source contact material 142 may be formed of and include one or more conductive materials. For example, the source contact material 142 may be formed of and include a polysilicon material (e.g., a doped polysilicon material), such as an N⁺ doped polysilicon material. The source contact material 142 may, alternatively, be formed of and include an un-doped polysilicon material and a doped polysilicon material. In some embodiments, the source contact material 142 is formed of and includes a doped polysilicon material including one or more of phosphorus and boron at a dopant amount (e.g., concentration). The source contact material 142 may substantially completely fill the source contact opening 140 and fill at least a portion of the opening 134. The source contact material 142 may contact (e.g., directly contact) the semiconductor material 104, the semiconductor material 114, and the channel material 128 and the cell films 130 of the pillars 124. While not illustrated in FIG. 1C, the source contact material 142 may also be formed on sidewalls of the tiers 122. The source contact material 142 may extend vertically between the upper surface of the semiconductor material 104 and the bottom surface of the semiconductor material 114. The source contact material 142 may be directly laterally adjacent to the channel material 128 and directly vertically adjacent to the cell films 130. The source contact material 142 may contact (e.g., directly contact) upper and lower surfaces of the cell films 130. The source contact material 142 may separate (e.g., segment) portions of the cell films 130 from additional portions thereof. The source contact material 142 may be operable coupled (e.g., electrically connected) to the base material 102 and the pillars 124. The source contact material 142 within the source contact opening 140 may have a substantially uniform thickness.

A portion of the source contact material 142 over the liner 136, over the sidewalls of the tiers 122, and over the upper surface of the dielectric material 132 may be removed by conventional techniques, such as by a wet etch process. Conventional etch chemistries and etch conditions may be used to remove the portion of the source contact material 142 depending on the material(s) used for the source contact material 142. The etch chemistries and etch conditions may selectively remove the portion of the source contact material 142 without substantially removing the liner 136. The stack structure 116 is protected from (e.g., not exposed to) the etch chemistries and etch conditions by the liner 136. An additional portion of the source contact material 142 vertically adjacent to the opening 134 may be removed to form a recess in the source contact material 142, as shown in FIG. 1C. A portion 144 of the source contact material 142 may be exposed through the opening 134.

FIG. 1E illustrates a simplified partial top-down cross-sectional view of the electronic structure 100 taken along the A-A line of FIG. 1D. Referring to FIG. 1D, a metal material 146 is selectively formed by conventional techniques over the exposed portion 144 of the source contact material 142. The metal material 146 may include and be formed of one of tungsten (W), molybdenum (Mo), cobalt (Co), or titanium (Ti). In some embodiments, the metal material 146 is formed by a CVD process using a metal halide precursor. The metal halide precursor includes and is formed of the same metal as the metal material 146. For example, the metal halide precursor may be a tungsten halide (e.g., tungsten fluoride, tungsten chloride, tungsten iodide, tungsten bromide), a molybdenum halide (e.g., molybdenum fluoride, molybdenum chloride, molybdenum iodide, molybdenum bromide), a cobalt halide (e.g., cobalt fluoride, cobalt chloride, cobalt iodide, cobalt bromide), or a titanium halide (e.g., titanium fluoride, titanium chloride, titanium iodide, titanium bromide). In some embodiments, the metal material 146 is tungsten (W) and tungsten hexafluoride (WF₆) is used as the metal halide precursor. The metal of the metal material 146 may be selected to be selectively removable (e.g., selectively etchable) relative to a metal silicide of the metal.

The metal material 146 substantially completely covers the exposed portion 144 of the source contact material 142, as shown in FIGS. 1D and 1E. Therefore, the metal material 146 is recessed within a portion of the source contact material 142. The metal material 146 may substantially continuously extend along horizontal and vertical exposed surfaces of the source contact material 142. The metal material 146 does not substantially extend over the liner 136. A thickness of the metal material 146 may be controlled by a dosage amount of the metal halide precursor and/or a duration (e.g., time) of the CVD process. The metal material 146 may be formed to have a thickness within a range of from about 1 nm to about 5 nm, such as from about 1 nm to about 2 nm, from about 1 nm to about 3 nm, from about 1 nm to about 4 nm, from about 2 nm to about 3 nm, from about 2 nm to about 4 nm, from about 2 nm to about 5 nm, from about 3 nm to about 4 nm, from about 3 nm to about 5 nm, or from about 4 nm to about 5 nm.

FIG. 1D depicts the metal material 146 directly adjacent to (e.g., in direct contact with) the source contact material 142. However, in some embodiments, a metal silicide material (not shown) may optionally be formed between the metal material 146 and the exposed portion 144 of the source contact material 142. For instance, when the source contact material 142 includes polysilicon, silicon atoms may diffuse from the source contact material 142 and into the metal material 146 to form the metal silicide material. The metal silicide material may be formed of and include tungsten silicide (WSiₓ), molybdenum silicide (MoSiₓ), cobalt silicide (CoSiₓ), or titanium silicide (TiSiₓ). The metal silicide material, if present, may substantially continuously extend along over the source contact material 142 and the metal material 146 may substantially continuously extend over the metal silicide material. The metal silicide material does not substantially extend over the liner 136. The metal silicide material may have a thickness of less than the thickness of the metal material 146. The metal silicide material and the metal material 146 may, therefore, form a bilayer over the source contact material 142.

FIG. 1G illustrates a simplified partial top-down cross-sectional view of the electronic structure 100 taken along the B-B line of FIG. 1F. Referring to FIG. 1F in combination with FIG. 1G, the electronic structure 100 may be annealed to convert at least a portion of the metal material 146 into a metal silicide material 148. During the anneal, silicon atoms from the source contact material 142 may diffuse into the metal material 146, forming the metal silicide material 148. The metal material 146 and the metal silicide material 148 may be selectively removable (e.g., selectively etchable) relative to one another under removal conditions (e.g., etch conditions) used in a subsequent process act. The metal material 146 may, for example, be selectively etchable relative to the metal silicide material 148 under etch conditions used in the replacement gate process. A horizontally oriented portion of the metal silicide material 148 is recessed within the source contact material 142. An upper surface of vertically oriented portions of the metal silicide material 148 may be at least substantially coplanar with a non-recessed portion of the source contact material 142 and with a lower surface of the semiconductor material 114. The U-shape of the metal silicide material 148 protects the underlying source contact material 142 from damage, such as from etch chemistries and conditions used in the replacement gate process.

Anneal conditions may be selected to convert a desired amount (e.g., portion, at least substantially all) of the metal material 146 into the metal silicide material 148. The electronic structure 100 may be annealed at a temperature within a range of from about 400° C. to about 1100° C., such as from about 400° C. to about 600° C., from about 400° C. to about 800° C., from about 500° C. to about 700° C., from about 500° C. to about 750° C., from about 500° C. to about 1000° C., from about 600° C. to about 800° C., from about 600° C. to about 700° C., from about 600° C. to about 900° C., from about 600° C. to about 1100° C., from about 700° C. to about 1000° C., from about 800° C. to about 1100° C., or from about 900° C. to about 1100° C. The electronic structure 100 may be annealed for a time period (e.g., duration) of at least about 1 second. For example, the electronic structure 100 may be annealed for a time period within a range of from about 1 second to about 10 seconds, such as from about 1 second to about 3 seconds, from about 2 seconds to about 4 seconds, from about 3 seconds to about 6 seconds, from about 4 seconds to about 6 seconds, from about 5 seconds to about 7 seconds, from about 6 seconds to about 8 seconds, from about 7 seconds to about 9 seconds, or from about 8 seconds to about 10 seconds. By appropriately selecting the temperature and duration of the anneal, the desired amount (e.g., a portion, at least substantially all) of the metal material 146 may be converted to the metal silicide material 148.

The metal silicide material 148 is formed in contact (e.g., in direct contact) with the source contact material 142 and the liner 136. FIGS. 1F and 1G depict substantially all of the metal material 146 converted into the metal silicide material 148, with the metal silicide material 148 substantially continuously extending over the source contact material 142. The metal silicide material 148 may be a stoichiometric metal silicide or a non-stoichiometric metal silicide. If substantially all of the metal material 146 is converted to the metal silicide material 148, the metal silicide material 148 may exhibit a substantially homogeneous composition of the metal silicide throughout its thickness or may exhibit a gradient of silicon throughout its thickness. A highest concentration of silicon atoms in the metal silicide material 148 may be present adjacent to (e.g., in direct contact with) the source contact material 142 while a lower concentration of the silicon atoms is present distal to the source contact material 142. A thickness of the metal silicide material 148 may be within a range of from about 1 nm to about 5 nm, such as from about 1 nm to about 2 nm, from about 1 nm to about 3 nm, from about 1 nm to about 4 nm, from about 2 nm to about 3 nm, from about 2 nm to about 4 nm, from about 2 nm to about 5 nm, from about 3 nm to about 4 nm, from about 3 nm to about 5 nm, or from about 4 nm to about 5 nm.

However, in some embodiments, only a portion of the metal material 146 in contact (e.g., in direct contact) with the source contact material 142 is converted into the metal silicide material 148. In such embodiments, the metal silicide material 148 is formed between the source contact material 142 and the metal material 146, with the metal material 146 substantially continuously extending over the metal silicide material 148. The metal silicide material 148 may be a stoichiometric metal silicide or a non-stoichiometric metal silicide. The metal silicide material 148 between the source contact material 142 and the metal material 146 may exhibit a substantially homogeneous composition throughout its thickness or may exhibit a gradient of silicon throughout its thickness. A bilayer of the metal silicide material 148 and the metal material 146 may, therefore, be present over the source contact material 142. A highest concentration silicon atoms in the metal silicide material 148 may be formed directly adjacent to (e.g., in direct contact with) the source contact material 142, while a lower concentration of silicon atoms in the metal silicide material 148 may be present distal to the source contact material 142. A total thickness of the metal material 146 and the metal silicide material 148 may be within a range of from about 1 nm to about 5 nm, such as from about 1 nm to about 2 nm, from about 1 nm to about 3 nm, from about 1 nm to about 4 nm, from about 2 nm to about 3 nm, from about 2 nm to about 4 nm, from about 2 nm to about 5 nm, from about 3 nm to about 4 nm, from about 3 nm to about 5 nm, or from about 4 nm to about 5 nm.

The metal silicide material 148 includes the same metal as the metal of the metal material 146 that is initially formed. For example, the metal silicide material 148 may be formed of and include tungsten silicide (WSiₓ), molybdenum silicide (MoSiₓ), cobalt silicide (CoSiₓ), or titanium silicide (TiSiₓ) if the metal material 146 is W, Mo, Co, or Ti, respectively. The metal silicide material 148 may include a stoichiometric metal silicide or a non-stoichiometric metal silicide. When the source contact material 142 includes a dopant, the metal silicide material 148 may include the dopant at a dopant amount. For example, the metal silicide material 148 may include one or more of boron and phosphorus at a dopant amount.

The metal silicide material 148 may substantially continuously extend over the exposed portion 144 of the source contact material 142. The metal silicide material 148 may substantially completely cover the exposed portion 144 of the source contact material 142, as shown in FIG. 1G. Vertically oriented portions of the metal silicide material 148 may be in contact (e.g., in direct contact) with lower surfaces of the liner 136 and horizontally oriented portions of the metal silicide material 148 may be in contact (e.g., in direct contact) with an exposed upper surface of the source contact material 142. Therefore, the metal silicide material 148 may be in direct contact with exposed sidewalls of the source contact material 142 and with the exposed upper surface of the source contact material 142. In some embodiments, the metal silicide material 148 does not extend over sidewalls of the tiers 122. Depending on the anneal conditions used, the metal silicide material 148 may be more dense (e.g., exhibit a higher density) than a density of the initially formed metal material 146. The increased density of the metal silicide material 148 may increase the degree of continuity of the metal silicide material 148 over the source contact material 142.

Referring to FIGS. 1H and 1I, additional process acts may be conducted to form features, such as semiconductor features, above, below, or adjacent to the source contact material 142 and the metal silicide material 148. The features may include, but are not limited to, transistors, capacitors, resistors, contacts, alignment marks, etc., depending on the electronic device to be formed. The features may be formed by conventional processes, which are not described in detail herein. The electronic structure 100 including the metal silicide material 148 may, for example, be used in a three-dimensional (3D) electronic device. The 3D electronic device may include, but is not limited to, a 3D NAND Flash memory device. The 3D electronic device may include, for example, word lines (e.g., access lines) above the source contact material 142. The word lines may be formed by replacing the nitride materials 118 of the tiers 122 with conductive materials 152 via the replacement gate process, as shown in FIG. 1H. The nitride materials 118 may be removed by conventional techniques, such as by a wet etch process, and the conductive materials 152 may be formed by conventional techniques. The conductive materials 152 may function as wordlines of the tiers 154. Conventional etch chemistries and etch conditions may be used to remove the nitride materials 118 depending on the material(s) used for the nitride materials 118. Since the metal material 146 is selectively etchable relative to the metal silicide material 148, the source contact material 142 is protected from (e.g., not exposed to) the etch chemistries and etch conditions by the metal silicide material 148 or a combination of the metal silicide material 148 and the metal material 146. The opening 134 may subsequently be filled with a fill material 156 following the replacement gate process. The fill material 156 may be a dielectric material or a conductive material. Additional process acts may be conducted to form the electronic device (e.g., the 3D NAND Flash memory device) including the electronic structure 100. The additional process acts for fabricating the electronic device may be conducted by conventional techniques, which are not described in detail herein.

Accordingly, a method of forming an electronic device includes forming a vertically-oriented opening through a stack structure, the stack structure including alternating nitride materials and dielectric materials adjacent to a source contact sacrificial structure, the source contact sacrificial structure adjacent to a source stack. The stack structure includes memory pillars extending through the alternating nitride materials and dielectric materials and into the source stack. The method further includes removing the source contact sacrificial structure to form a source contact opening between the alternating nitride materials and dielectric materials and the source stack, forming a source contact material in the source contact opening, forming a metal material on sidewalls and an upper surface of the source contact material in the vertically-oriented opening, and converting at least a portion of the metal material to a metal silicide material on the source contact material.

The metal material 146 exhibits a significantly lower etch rate relative to the nitride materials 118 when exposed to etch chemistries and conditions used in the replacement gate process to form word lines by replacing the nitride materials 118 with conductive materials 152. The metal silicide material 148 exhibits a significantly lower etch rate than each of the metal material 146 and the nitride materials 118 when exposed to the etch chemistries and conditions used in the replacement gate process. Therefore, the metal material 146, the metal material 146 in combination with the metal silicide material 148, or the metal silicide material 148 may each be used to protect the source contact material 142 from exposure to the etch chemistries and conditions used in the replacement gate process. The source contact material 142, therefore, does not exhibit degradation following the replacement gate process, improving performance, reliability, and durability of the source contact material 142.

While FIG. 1H shows the electronic structure 100 having substantially all of the metal material 146 converted to the metal silicide material 148 after conducting the replacement gate process, the electronic structure 100 may include a combination of the metal material 146 and the metal silicide material 148 if less than all (e.g., less than substantially all) of the metal material 146 is converted into the metal silicide material 148. In other words, the electronic structure 100 may include a substantially homogeneous composition of the metal silicide material 148, a gradient of silicon in the metal silicide material 148, or a bilayer of the metal silicide material 148 and the metal material 146 to protect the source contact material 142.

Accordingly, an electronic device includes a source contact adjacent to a source stack, the source contact including one or more conductive materials, tiers of alternating conductive materials and dielectric materials adjacent to the source contact, pillars extending vertically through the tiers and the source contact and at least partially into the source stack, a fill material extending vertically through the tiers to the source contact, and a metal silicide material between the fill material and an upper surface of the source contact.

Accordingly, a memory device includes a stack including tiers of alternating conductive structures and dielectric structures overlying a source stack, pillars extending vertically through the stack and into the source stack, the pillars comprising a channel material, a source contact laterally adjacent to the pillars and electrically connected to the channel material of the pillars, and a metal silicide material directly contacting an upper surface of the source contact, the metal silicide material below the tiers and over the source contact.

FIG. 2 illustrates a partial cutaway perspective view of a portion of an electronic device 200 (e.g., a microelectronic device, a memory device, such as a 3D NAND Flash memory device) including an electronic structure 202. The electronic structure 202 may be substantially similar to the electronic structure 100 including the metal silicide material 148 or the metal material 146 and the metal silicide material 148, previously described with reference to FIGS. 1A-1I. For convenience in describing FIG. 2, a first direction is defined as the X-direction. A second direction, which is transverse (e.g., perpendicular) to the first direction is defined as the Y-direction. A third direction, which is transverse to the first and second directions is defined as the Z-direction.

As shown in FIG. 2, the electronic device 200 may include a staircase structure 204 defining contact regions for connecting routing lines 206 to conductive structures 208 (e.g., word lines, access lines, corresponding to the conductive materials formed in electronic structure 100 by the replacement gate process). The electronic structure 202 may include vertical strings 210 of memory cells 212 (e.g., corresponding to the pillars 124 (FIG. 1H)), that are coupled to each other in series. The vertical strings 210 may extend vertically (e.g., in the Z-direction) and orthogonally to conductive lines and the conductive structures 208, such as data lines 214, a source tier 216 (e.g., corresponding to the base material 102 (FIG. 1H)), first select gates 218 (e.g., upper select gates, drain select gates (SGDs)), select lines 220, and a second select gate 222 (e.g., a lower select gate, a source select gate (SGS)). The first select gates 218 may be horizontally divided in the second direction (e.g., in the Y-direction) into multiple blocks 224 horizontally separated from one another by slots 226.

Vertical conductive contacts 228 may electrically couple components to each other as shown. For example, the select lines 220 may be electrically coupled to the first select gates 218 and the routing lines 206 may be electrically coupled to the conductive structures 208. The electronic device 200 may also include a control unit 230 positioned under the memory array, which may include one or more of string driver circuitry, pass gates, circuitry for selecting gates, circuitry for selecting conductive lines (e.g., the data lines 214, the routing lines 206), circuitry for amplifying signals, and circuitry for sending signals. The control unit 230 may be electrically coupled to the data lines 214, the source tier 216, the routing lines 206, the first select gates 218, and the second select gate 222, for example. In some embodiments, the control unit 230 includes CMOS (complementary metal-oxide-semiconductor) circuitry. In such embodiments, the control unit 230 may be characterized as having a “CMOS under Array” (“CuA”) configuration.

The first select gates 218 may extend horizontally in a first direction (e.g., the X-direction) and may be coupled to respective first groups of vertical strings 210 of memory cells 212 at a first end (e.g., an upper end) of the vertical strings 210. The second select gate 222 may be formed in a substantially planar configuration and may be coupled to the vertical strings 210 at a second, opposite end (e.g., a lower end) of the vertical strings 210 of memory cells 212.

The data lines 214 (e.g., digit lines, bit lines) may extend horizontally in a second direction (e.g., in the Y-direction) that is at an angle (e.g., perpendicular) to the first direction (e.g., the X-direction) in which the first select gates 218 extend. Individual data lines 214 may be coupled to individual groups of the vertical strings 210 extending in the second direction (e.g., the Y-direction) at the first end (e.g., the upper end) of the vertical strings 210 of the individual groups. Additional individual groups of the vertical strings 210 extending in the first direction (e.g., the X-direction) and coupled to individual first select gates 218 may share a particular vertical string 210 thereof with individual groups of vertical strings 210 coupled to an individual data line 214. Thus, an individual vertical string 210 of memory cells 212 may be selected at an intersection of an individual first select gate 218 and an individual data line 214. Accordingly, the first select gates 218 may be used for selecting memory cells 212 of the vertical strings 210 of memory cells 212.

The conductive structures 208 (e.g., word lines) may extend in respective horizontal planes. The conductive structures 208 may be stacked vertically, such that each conductive structure is coupled to at least some of the vertical strings 210 of memory cells 212, and the vertical strings 210 of the memory cells 212 extend vertically through the stack structure (e.g., the stack structure 116) including the conductive structures 208. The conductive structures 208 may be coupled to or may form control gates of the memory cells 212.

The first select gates 218 and the second select gate 222 may operate to select a vertical string 210 of memory cells 212 interposed between data lines 214 and the source tier 216. Thus, an individual memory cell 212 may be selected and electrically coupled to a data line 214 by operation of (e.g., by selecting) the appropriate first select gate 218, second select gate 222, and conductive structure 208 that are coupled to the particular memory cell 212.

The staircase structure 204 may be configured to provide electrical connection between the routing lines 206 and the conductive structures 208 through the vertical conductive contacts 228. In other words, an individual conductive structure 208 may be selected via a routing line 206 in electrical communication with a respective vertical conductive contact 228 in electrical communication with the conductive structure 208. The data lines 214 may be electrically coupled to the vertical strings 210 of memory cells 212 through conductive contact structures 232.

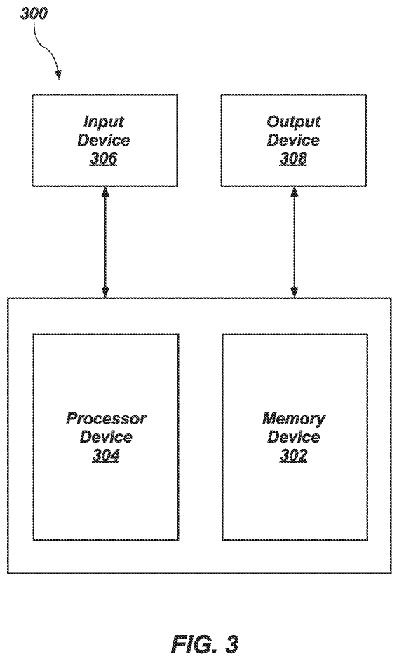

Electronic devices (e.g., the electronic device 200) including one or more electronic structures (e.g., the electronic structure 100) including the metal silicide material 148 or the metal material 146 and the metal silicide material 148, according to embodiments of the disclosure, may be used in embodiments of electronic systems of the disclosure. For example, FIG. 3 is a block diagram of an electronic system 300 implemented according to one or more embodiments described herein. The electronic system 300 may include, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 300 includes at least one memory device 302. The memory device 302 may include, for example, the electronic structure previously described herein (e.g., the electronic structure 100 previously described with reference to FIGS. 1A-1I) including the metal silicide material 148 or the metal material 146 and the metal silicide material 148.

The electronic system 300 may further include at least one electrical signal processor device 304 (e.g., a processor or a microprocessor). The electrical signal processor device 304 may, optionally, include at least one electronic structure 100 according to embodiments of the disclosure. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 may include a single device that can be used both to input information to the electronic system 300 and to output information to a user. For example, the input device 306 and the output device 308 may include a single touchscreen device that can input information from a user to the electronic system 300 and output visual information to a user. The one or more input devices 306 and the output devices 308 may communicate electrically with at least one of the memory device 302 and the electrical signal processor device 304.

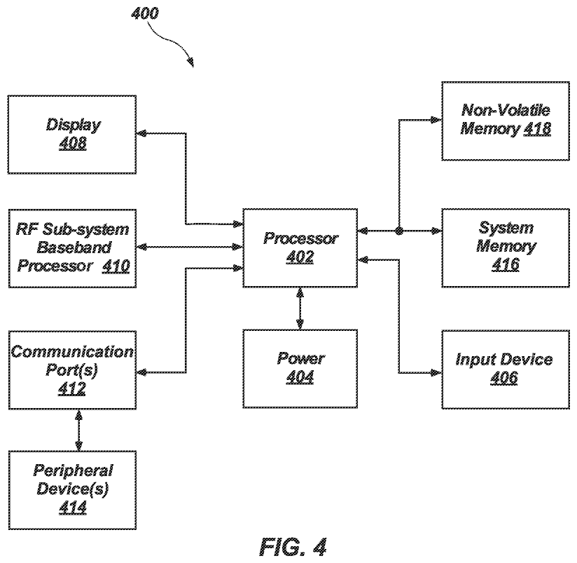

With reference to FIG. 4, a processor-based system 400 is depicted. The processor-based system 400 may include various electronic structures (e.g., the electronic structure 100) manufactured in accordance with embodiments of the disclosure. The processor-based system 400 may be any of a variety of types such as a computer, pager, cellular phone, personal organizer, control circuit, or other electronic device. The processor-based system 400 may include one or more processors 402, such as a microprocessor, to control the processing of system functions and requests in the processor-based system 400. The processor 402 and other subcomponents of the processor-based system 400 may include electronic structures (e.g., the electronic structure 100) or electronic devices (e.g., the electronic device 200) manufactured in accordance with embodiments of the disclosure.

The processor-based system 400 may include a power supply 404 in operable communication with the processor 402. For example, if the processor-based system 400 is a portable system, the power supply 404 may include one or more of a fuel cell, a power scavenging device, permanent batteries, replaceable batteries, and rechargeable batteries. The power supply 404 may also include an AC adapter; therefore, the processor-based system 400 may be plugged into a wall outlet, for example. The power supply 404 may also include a DC adapter such that the processor-based system 400 may be plugged into a vehicle cigarette lighter or a vehicle power port, for example.

Various other devices may be coupled to the processor 402 depending on the functions that the processor-based system 400 performs. For example, a user interface 406 may include input devices such as buttons, switches, a keyboard, a light pen, a mouse, a digitizer and stylus, a touch screen, a voice recognition system, a microphone, or a combination thereof. A display 408 may also be coupled to the processor 402. The display 408 may include an LCD display, an SED display, a CRT display, a DLP display, a plasma display, an OLED display, and LED display, a three-dimensional projection, an audio display, or a combination thereof. Furthermore, an RF sub-system/baseband processor 410 may also be coupled to the processor 402. The RF sub-system/baseband processor 410 may include an antenna that is coupled to an RF receiver and to an RF transmitter (not depicted). A communication port 412, or more than one communication port 412, may also be coupled to the processor 402. The communication port 412 may be adapted to be coupled to one or more peripheral devices 414, such as a modem, a printer, a computer, a scanner, or a camera, or to a network, such as a local area network, remote area network, intranet, or the Internet, for example.

The processor 402 may control the processor-based system 400 by implementing software programs stored in the memory. The software programs may include an operating system, database software, drafting software, word processing software, media editing software, or media playing software, for example. The memory is operably coupled to the processor 402 to store and facilitate execution of various programs. For example, the processor 402 may be coupled to system memory 416, which may include one or more of spin torque transfer magnetic random access memory (STT-MRAM), magnetic random access memory (MRAM), dynamic random access memory (DRAM), static random access memory (SRAM), racetrack memory, and other known memory types. The system memory 416 may include volatile memory, non-volatile memory, or a combination thereof. The system memory 416 is typically large so that it can store dynamically loaded applications and data. In some embodiments, the system memory 416 may include electronic structures, such as the electronic structures (e.g., the electronic structure 100) according to the embodiments of the disclosure, or a combination thereof.

The processor 402 may also be coupled to non-volatile memory 418. The non-volatile memory 418 may include one or more of STT-MRAM, MRAM, read-only memory (ROM) such as an EPROM, resistive read-only memory (RROM), and flash memory to be used in conjunction with the system memory 416. The size of the non-volatile memory 418 is typically selected to be just large enough to store any necessary operating system, application programs, and fixed data. Additionally, the non-volatile memory 418 may include a high-capacity memory such as a disk drive memory, such as a hybrid-drive including resistive memory or other types of non-volatile solid-state memory, for example. The non-volatile memory 418 may include electronic structures, such as the electronic structures (e.g., the electronic structure 100) according to the embodiments of the disclosure, or a combination thereof.

Accordingly, a system includes a processor operably coupled to an input device and an output device, and one or more memory devices operably coupled to the processor, the one or more memory devices including at least one electronic device. The at least one electronic device includes a source contact vertically adjacent to a source stack, a first semiconductor material over the source contact, memory pillars vertically extending through a stack of alternating dielectric materials and conductive materials, the first semiconductor material, and the source contact, and at least partially into the source stack, the memory pillars operably coupled to the source contact, and a metal silicide material directly vertically adjacent to the source contact.

The electronic structures 100, electronic devices 200, and systems 300 and 400 of the disclosure advantageously facilitate one or more of improved simplicity, improved performance, durability, reliability, and increased protection of components during fabrication as compared to conventional structures, conventional devices, and conventional systems. The methods of the disclosure facilitate the formation of devices (e.g., apparatuses, microelectronic devices, memory devices) and systems (e.g., electronic systems) while avoiding degradation of components, improving performance, reliability, and durability, decreasing costs, and/or increasing yield as compared to conventional methods of formation of conventional devices (e.g., conventional apparatuses, conventional microelectronic devices, conventional memory devices) and conventional systems (e.g., conventional electronic systems).

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modification to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An electronic device, comprising:
a source contact adjacent to a source stack, the source contact comprising one or more conductive materials;
tiers of alternating conductive materials and dielectric materials adjacent to the source contact;
pillars extending vertically through the tiers and the source contact and at least partially into the source stack;
a fill material extending vertically through the tiers to the source contact; and
a metal silicide material between the fill material and an upper surface of the source contact.

2. The electronic device of claim 1, further comprising a metal material adjacent to the metal silicide material, the metal material comprising the same metal as the metal material of the metal silicide material.

3. The electronic device of claim 1, wherein the metal silicide material comprises one or more of tungsten silicide, molybdenum silicide, cobalt silicide, and titanium silicide.

4. The electronic device of claim 1, wherein the metal silicide material directly contacts sidewalls of the source contact and sidewalls of the fill material.

5. The electronic device of claim 4, wherein the metal silicide material does not extend over sidewalls of the tiers.

6. The electronic device of claim 1, wherein the metal silicide material has a thickness within a range of from about 1 nm to about 5 nm.

7. The electronic device of claim 1, wherein the metal silicide material comprises a stoichiometric metal silicide.

8. The electronic device of claim 1, wherein the metal silicide material comprises a non-stoichiometric metal silicide.

9. A memory device, comprising:
a stack comprising tiers of alternating conductive structures and dielectric structures overlying a source stack;
pillars extending vertically through the stack and into the source stack, the pillars comprising a channel material;
a source contact laterally adjacent to the pillars and electrically connected to the channel material of the pillars; and
a metal silicide material directly contacting an upper surface of the source contact, the metal silicide material below the tiers and over the source contact.

10. The memory device of claim 9, further comprising a fill material vertically adjacent to the metal silicide material and laterally adjacent to the tiers.

11. The memory device of claim 9, wherein the metal silicide material is substantially homogeneous in composition.

12. A system, comprising:
a processor operably coupled to an input device and an output device; and
one or more memory devices operably coupled to the processor and comprising at least one electronic device, the at least one electronic device comprising:
a source contact vertically adjacent to a source stack;
a first semiconductor material over the source contact;
memory pillars vertically extending through a stack of alternating dielectric materials and conductive materials, the first semiconductor material, and the source contact, and at least partially into the source stack, the memory pillars operably coupled to the source contact; and
a metal silicide material directly vertically adjacent to the source contact.

13. The system of claim 12, wherein the metal silicide material does not extend over sidewalls of the first semiconductor material.

14. The system of claim 12, wherein the metal silicide material comprises a gradient of silicon in the metal silicide material.

15. A method of forming an electronic device, the method comprising:
forming a vertically-oriented opening through a stack structure, the stack structure comprising:
alternating nitride materials and dielectric materials adjacent to a source contact sacrificial structure, the source contact sacrificial structure adjacent to a source stack; and
memory pillars extending through the alternating nitride materials and dielectric materials and into the source stack;
removing the source contact sacrificial structure to form a source contact opening between the alternating nitride materials and dielectric materials and the source stack;
forming a source contact material in the source contact opening;
forming a metal material on sidewalls and an upper surface of the source contact material in the vertically-oriented opening; and
converting at least a portion of the metal material to a metal silicide material on the source contact material.

16. The method of claim 15, wherein forming a metal material on sidewalls and an upper surface of the source contact material comprises forming the metal material on the source contact material by chemical vapor deposition using a metal halide precursor.

17. The method of claim 16, wherein:
forming a metal material on sidewalls and an upper surface of the source contact material comprises forming tungsten on the sidewalls and the upper surface of the source contact material;
forming the metal material on the source contact material using a metal halide precursor comprises forming the metal material using tungsten hexafluoride; and
converting at least a portion of the metal material to a metal silicide material comprises converting at least a portion of the tungsten to tungsten silicide.

18. The method of claim 15, wherein forming a metal material on sidewalls and an upper surface of the source contact material comprises forming the metal material comprising one or more of tungsten, molybdenum, cobalt, and titanium.

19. The method of claim 15, wherein converting at least a portion of the metal material to a metal silicide material comprises diffusing silicon from the source contact material comprising polysilicon to form the metal silicide material.

20. The method of claim 15, wherein converting at least a portion of the metal material to a metal silicide material comprises annealing the metal material to form the metal silicide material.

21. The method of claim 20, wherein annealing the metal material comprises heating the metal material to a temperature within a range of from about 400° C. to about 1100° C.

22. The method of claim 15, wherein converting at least a portion of the metal material to a metal silicide material comprises forming the metal silicide material comprising a substantially homogeneous composition of the metal silicide material.

23. The method of claim 15, wherein converting at least a portion of the metal material to a metal silicide material comprises forming a gradient of silicon in the metal silicide material.

24. The method of claim 15, wherein converting at least a portion of the metal material to a metal silicide material comprises forming a bilayer of the metal material and the metal silicide material.

25. The method of claim 15, further comprising forming a fill material in the vertically-oriented opening, the fill material in direct contact with the metal silicide material.

26. The method of claim 15, further comprising:
selectively removing the nitride materials to form first openings in the stack structure without substantially removing of the metal silicide material and the source contact material; and
forming a conductive material in the first openings.
